(19) United States
(12) Patent Application Publication
(10) Pub. No.: US 2023/0018215 A1
(43) Pub. Date: Jan. 19, 2023

(54) NOISE INTRUSION POSITION ESTIMATION DEVICE AND NOISE INTRUSION POSITION ESTIMATION METHOD

(71) Applicant: Mitsubishi Electric Corporation, Tokyo (JP)

(72) Inventors: Koji SHIBUYA, Tokyo (JP); Tetsu OWADA, Tokyo (JP)

(73) Assignee: Mitsubishi Electric Corporation, Tokyo (JP)

(21) Appl. No.: 17/950,349

(22) Filed: Sep. 22, 2022

Related U.S. Application Data
(63) Continuation of application No. PCT/JP2020/017101, filed on Apr. 20, 2020.

(51) Int. Cl. G01R 31/08

(52) U.S. Cl. CPC G01R 31/088; G01R 31/085

(57) ABSTRACT

A noise intrusion position estimation device includes: a measurement unit including a pair of detection units to simultaneously measure a temporal change of waveforms of noise on a transmission cable at two separated observation points in the transmission cable; and a calculation unit to receive, from the measurement unit a pair of the waveforms of the noise simultaneously measured, to time-reverse the pair of the waveforms of the noise that has been received, to perform transmission path analysis in which the two observation points are set as positions of signal sources of the time-reversed noise and the time-reversed waveforms are set as excitation waveforms in a transmission line model in which electrical characteristics of the transmission cable are represented, and to output a position of a peak value obtained from a result of the transmission path analysis as an intrusion position of the noise into the transmission cable.

### CROSS REFERENCE TO RELATED APPLICATIONS

This application is a Continuation of PCT International Application No. PCT/JP2020/017101, filed on Apr. 20, 2020, all of which is hereby expressly incorporated by reference into the present application.

### TECHNICAL FIELD

The present disclosure relates to a noise intrusion position estimation device and a noise intrusion position estimation method for estimating, in a case where noise is superimposed on a transmission cable, a position in the transmission cable from which the superimposed noise has entered.

### BACKGROUND ART

As technology for estimating a noise intrusion position from a noise waveform instead of manually searching a vicinity of the cable when noise superimposed on the cable is searched for, Patent Literature 1 discloses a noise detection method for detecting noise due to partial electric discharge that occurs in a high-voltage power cable.

In the noise detection method according to Patent Literature 1, a mixing spot of noise and the noise intensity at the mixing spot are obtained on the basis of the noise intensities at sensor positions obtained from signals detected by a plurality of sensors arranged over a cable to be diagnosed, the length of the cable between the sensors, and the attenuation rate when the noise travels through the cable.

### CITATION LIST

### Patent Literatures

Patent Literature 1: JP 2001-133503 A

### SUMMARY OF INVENTION

### Technical Problem

With respect to noise caused by partial electric discharge that occurs in a high-voltage power cable, a mixing spot of the noise and the noise intensity at the mixing spot can be obtained on the basis of the attenuation rate when the noise travels through the cable.

However, in a transmission cable that propagates a high-frequency signal, a noise waveform greatly varies due to influences of multipath reflection or mode conversion in the transmission cable caused by a non-uniform common mode impedance distribution of the transmission cable. Therefore, it is difficult to estimate from which position in the transmission cable the superimposed noise has entered on the basis of an attenuation rate of the noise that is propagated.

In addition, in a transmission cable used in a balanced transmission path, it is also difficult to estimate a position where noise having entered in a common mode is converted into a differential mode which is a normal mode, that is, an unbalanced position.

The present disclosure solves the above problems, and an object of the present disclosure is to obtain a noise intrusion position estimation device capable of estimating an intrusion position of high-frequency noise in a transmission cable with respect to the high-frequency noise propagated through the transmission cable under the influence of multipath reflection and mode conversion.

### Solution to Problem

A noise intrusion position estimation device according to the present disclosure includes: a measurement device comprising a pair of pairs of detectors to simultaneously measure a temporal change of waveforms of noise on a transmission cable at two separated observation points in the transmission cable comprising a pair of signal conductors; and a processing circuitry to receive, from the measurement device, a pair of pairs of the waveforms of the noise simultaneously measured, to time-reverse the pair of the pairs of the waveforms of the noise that has been received, to perform transmission path analysis in which the two separated observation points are set as positions of signal sources of the time-reversed noise and the time-reversed waveforms are set as excitation waveforms in a transmission line model in which an electrical characteristic of the transmission cable is represented, and to output a position of a peak value among mode voltage values obtained from a result of the transmission path analysis as an intrusion position of the noise into the transmission cable, wherein, in calculation of the mode voltage values performed by the processing circuitry, the time-reversed waveforms are used in the calculation as waveforms of a common mode for obtaining ½ of a sum of voltages in each of a first pair of detectors and a second pair of detectors of the pair of the pairs of the detectors, and the intrusion position of the noise output by the processing circuitry is set as a common noise intrusion position which is a position of a peak value among voltage values of the common mode obtained from a result of transmission path analysis performed on a basis of the waveforms of the common mode.

### Advantageous Effects of Invention

According to the present disclosure, it is possible to estimate an intrusion position of high-frequency noise propagated through a transmission cable.

### BRIEF DESCRIPTION OF DRAWINGS

FIG. 1 is a configuration diagram illustrating a noise intrusion position estimation device according to a first embodiment.

FIG. 2 is a schematic diagram illustrating a measurement form of the noise intrusion position estimation device according to the first embodiment.

FIG. 3 is a schematic diagram illustrating generation of time reversal signals of noise waveforms in a transmission cable of the noise intrusion position estimation device according to the first embodiment.

FIG. 4 is a schematic diagram of voltage distribution calculation to trace back in time performed by the noise intrusion position estimation device according to the first embodiment.

FIG. 5 is a flowchart illustrating an operation of a calculation unit in the noise intrusion position estimation device according to the first embodiment.

FIG. 6 is a configuration diagram illustrating a noise intrusion position estimation device according to a second embodiment.

FIG. 7 is a schematic diagram illustrating a measurement form of the noise intrusion position estimation device according to the second embodiment.

FIG. 8 is a flowchart illustrating an operation of a calculation unit in the noise intrusion position estimation device according to the second embodiment.

### DESCRIPTION OF EMBODIMENTS

### First Embodiment

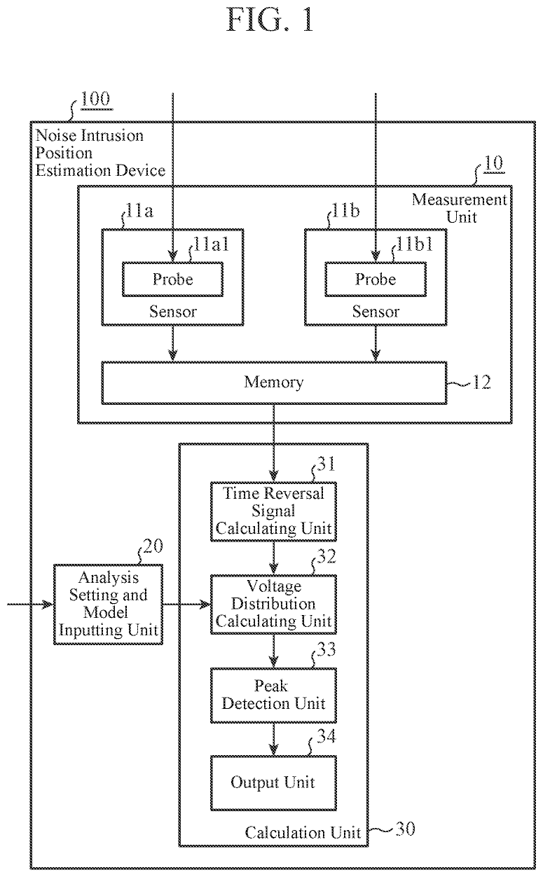

A noise intrusion position estimation device 100 according to a first embodiment will be described with reference to FIGS. 1 to 5.

The noise intrusion position estimation device 100 includes a measurement unit 10, an analysis setting and model inputting unit 20, and a calculation unit 30.

The measurement unit 10 simultaneously measures a temporal change of the waveform of noise superimposed on a transmission cable 40 to be measured at two separated observation points in the transmission cable 40, that is, observation points at both ends of the transmission cable 40 in the first embodiment.

The transmission cable 40 includes a signal conductor that propagates a high-frequency signal.

The measurement unit 10 includes a pair of sensor 11a and sensor 11b and a storage unit 12.

Each of the sensor 11a and the sensor 11b detects a temporal change in the waveform of noise superimposed on the transmission cable 40. The sensor 11a and the sensor 11b are detection units that simultaneously measure the temporal change of the waveform of noise. In the first embodiment, a device for estimating an intrusion position of high-frequency noise into the transmission cable 40 including one signal conductor will be described.

Note that, in a case of estimating an intrusion position of high-frequency noise into the transmission cable 40 including a plurality of signal conductors, the measurement unit 10 includes a pair of the sensor 11a and the sensor 11b for each of the plurality of signal conductors. In order to simplify the description, the transmission cable 40 including a single signal conductor will be described below.

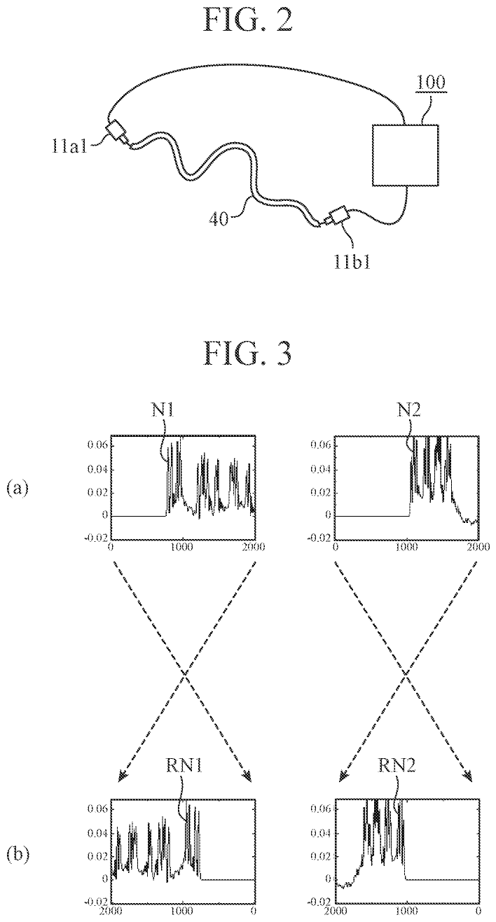

The sensor 11a and the sensor 11b include a probe 11a1 and a probe 11b1, respectively. As illustrated in FIG. 2, the probe 11a1 of the first sensor 11a is connected to a first end of the transmission cable 40, that is, an observation point on the first end side. As illustrated in FIG. 2, the probe 11b1 of the second sensor 11b is connected to a second end of the transmission cable 40, that is, an observation point on the second end side.

When noise enters a specific position in the transmission cable 40, the noise is propagated through the transmission cable 40, and the sensor 11a and the sensor 11b simultaneously observe noise waveforms as the voltage with respect to time at the observation points at both ends of the transmission cable 40.

The storage unit 12 includes a memory and stores waveforms of the noise simultaneously measured, by the sensor 11a and the sensor 11b, at the respective ends of the transmission cable 40 that are observation points, as waveforms of the noise having temporal changes that have been simultaneously measured.

The analysis setting and model inputting unit 20 sets a transmission line model 40S on the basis of the electrical characteristics of the transmission cable 40 and outputs the transmission line model 40S to the calculation unit 30.

The analysis setting and model inputting unit 20 outputs a minute time Δt to the calculation unit 30. The cell size and the minute time Δt of the transmission line model 40S are about 1/10 of the wavelength of a major frequency component of the waveform of the noise that is to be measured.

In the first embodiment, the analysis setting and model inputting unit 20 sets the transmission line model 40S and the minute time Δt in advance by representing the electrical characteristics of the transmission cable 40. However, the analysis setting and model inputting unit 20 may be configured to generate the transmission line model 40S and the minute time Δt from waveforms of noise propagated through the transmission cable 40 and detected by the sensors 11a and 11b or the like.

The calculation unit 30 receives, from the measurement unit 10, a pair of noise waveforms that has been simultaneously measured, time-reverses the pair of noise waveforms that has been received, performs transmission path analysis that reverses time on the basis of time-reversed noise waveforms by setting two observation points of the measurement unit 10 as signal sources of the time-reversed noise in the transmission line model 40S obtained from the analysis setting and model inputting unit 20, and outputs the position of a peak value obtained from the transmission path analysis result as the intrusion position of the noise.

The calculation unit 30 includes a time reversal signal calculating unit 31, a voltage distribution calculating unit 32, a peak detection unit 33, and an output unit 34 and is configured by a CPU or a microprocessor.

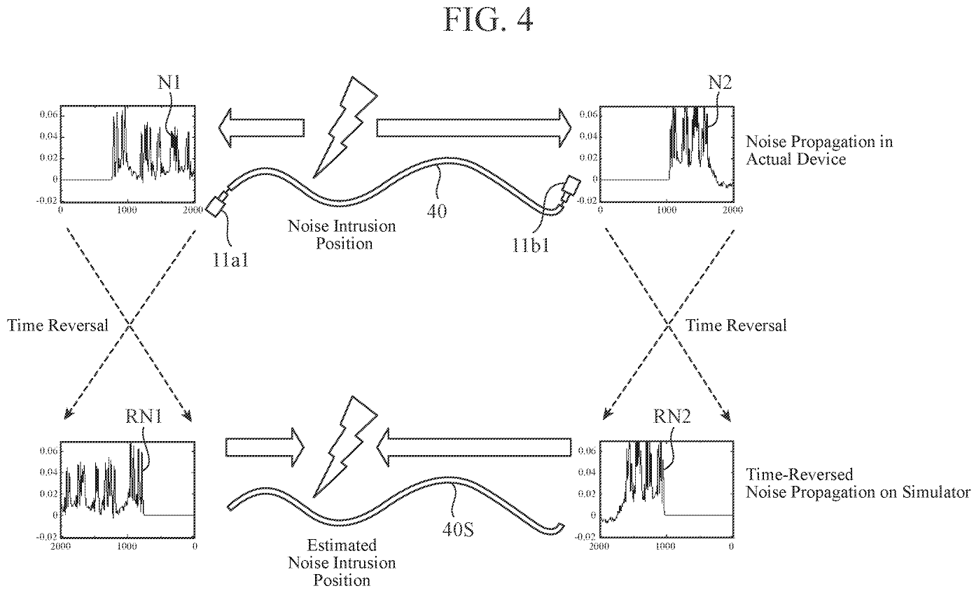

The time reversal signal calculating unit 31 receives a pair of noise waveforms N1 and N2 measured simultaneously and stored in the storage unit 12 of the measurement unit 10 illustrated in FIG. 3A, time-reverses each of the pair of noise waveforms N1 and N2, and converts each of the noise waveforms N1 and N2 into time reversal signals RN1 and RN2 illustrated in FIG. 3B. The time reversal signals RN1 and RN2 are obtained by rearranging data indicating the noise waveforms N1 and N2, respectively, in a reverse order with respect to time.

The voltage distribution calculating unit 32 receives the transmission line model 40S from the analysis setting and model inputting unit 20 and the time reversal signals RN1 and RN2 from the time reversal signal calculating unit 31 and performs transmission path analysis in which time is traced back and, as illustrated in FIG. 4B, observation points of the measurement unit 10, that is, both ends of the transmission cable 40 are set as the positions of signal sources of the time reversal signals RN1 and RN2 in the transmission line model 40S and the time reversal signals RN1 and RN2 are used as excitation waveforms. For this transmission path analysis, that is, for signal transmission simulation in the time domain, a finite difference time domain method (FDTD method) is used.

That is, the voltage distribution calculating unit 32 calculates the voltage current distribution at time t, and calculates the voltage current distribution at time (t−Δt×n) obtained by subtracting the minute time Δt set by the analysis setting and model inputting unit 20 from the voltage current distribution at time t. The symbol n represents the number of steps from 1 to N, and where n=N, the relation (t−Δt×n)≤0 holds, and the voltage distribution calculating unit 32 ends the calculation.

Note that the end time of the calculation may be a set to a time when a transmission path analysis result indicates a peak value in the peak detection unit 33, the number of times of repetitions in which the number of times of subtracting the minute time Δt is set, or a set rewinding time in which the time reversal is performed.

In addition, in a case where the loss of the transmission cable 40 is sufficiently small and there is no irreversible structure in the transmission line model 40S, in the FDTD method, a generally-performed signal transmission simulation in which the time advances, that is, an approach in which a voltage current distribution at a time (t+Δt×n) obtained by adding the minute time Δt to time t is calculated may be used. In this case, since existing software can be used, there is an advantage that the cost can be reduced.

The peak detection unit 33 receives the transmission path analysis results, obtained every time the minute time Δt is subtracted, from the voltage distribution calculating unit 32, and detects the position of the peak value obtained from the transmission path analysis results as the intrusion position of noise into the transmission cable 40.

Since in the transmission path analysis results from the voltage distribution calculating unit 32, the waveform changes of the time reversal signals RN1 and RN2 behave in such a manner that time is traced back, it is possible to finally estimate the noise inflow position on the basis of the position of a peak value in the transmission path analysis results by observing the transmission path analysis results while reversely reproducing multipath reflection, mode conversion, and the like, that is, while performing time reversal. That is, the estimated noise inflow position on a simulator can be specified as illustrated in FIG. 4B.

The output unit 34 outputs the estimated noise inflow position on the simulator specified by the peak detection unit 33 to a monitor (not illustrated) as the noise inflow position in the transmission cable 40 as illustrated in A of FIG. 4.

Next, the operation of the noise intrusion position estimation device 100 will be described.

When high-frequency noise is superimposed on the transmission cable 40 to be measured, the pair of sensors 11a and 11b of the measurement unit 10 detects the high-frequency noise via the pair of probes 11a1 and 11b1 connected to two separated observation points in the signal conductor in the transmission cable 40 and simultaneously measures the temporal change of the noise waveforms.

The noise waveforms having temporal changes that have been simultaneously measured by the pair of sensors 11a and 11b are stored in the storage unit. The above steps are measurement steps.

The noise waveforms having temporal changes that have been simultaneously measured and are stored in the storage unit 12 are read by the calculation unit 30, and the calculation unit 30 estimates the noise intrusion position in the transmission cable 40.

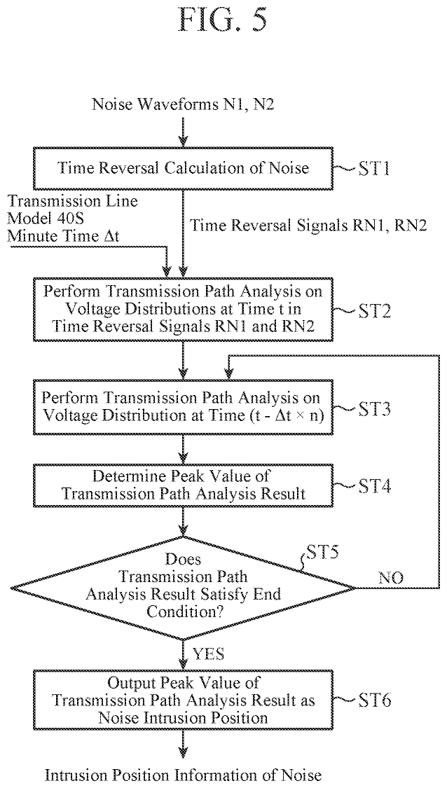

The operation of estimating the noise intrusion position performed by the calculation unit 30 will be described with reference to a flowchart illustrated in FIG. 5.

First, in step ST1, the pair of noise waveforms N1 and N2 that has been simultaneously measured and input is time-reversed and converted into the time reversal signals RN1 and RN2, respectively, by the time reversal signal calculating unit 31.

Next, in step ST2, the voltage distribution calculating unit 32 sets both ends of the transmission cable 40 as the positions of the signal sources of the time reversal signals RN1 and RN2 in the transmission line model 40S from the analysis setting and model inputting unit 20. The voltage distribution calculating unit 32 performs the transmission path analysis using the FDTD method in which the time is traced back and the time reversal signals RN1 and RN2 from the time reversal signal calculating unit 31 are used as excitation waveforms. First, the voltage distribution calculating unit 32 calculates the voltage current distributions at time tin the time reversal signals RN1 and RN2 and provides the calculation result to the peak detection unit 33.

In step ST3, the voltage current distributions at time t−Δt (n=1) in the time reversal signals RN1 and RN2 are calculated, and the calculation result is provided to the peak detection unit 33.

In step ST4, the peak detection unit 33 determines peak values from the voltage current distributions in the time reversal signals RN1 and RN2 from the voltage distribution calculating unit 32 and the process proceeds to step ST5.

In step ST5, it is determined whether or not the transmission path analysis result satisfies any one of the end conditions of (t−Δt×n)≤0, satisfying the number of times of repetitions of calculation by the voltage distribution calculating unit 32, or satisfying the rewinding time.

If no end condition is satisfied, Δt is multiplied by a value obtained by adding 1 to the value of n, the process returns to step ST3, and the voltage current distributions in the time reversal signals RN1 and RN2 at time t−Δt×2 (n=2) are calculated. Then the process proceeds to step ST4 and step ST5, and step ST5→step ST3→step ST4→step ST5 are repeated until the transmission path analysis result satisfies an end condition in step ST5.

That is, the voltage distribution calculating unit 32 calculates voltage current distributions in the time reversal signals RN1 and RN2 by tracing back the time from time t until an end condition is satisfied.

In step ST5, if the transmission path analysis result satisfies an end condition, the process proceeds to step ST6, and the output unit 34 outputs the position of a peak value obtained from the transmission path analysis result by the peak detection unit 33 to the monitor as the noise intrusion position in the transmission cable 40.

As a result, the monitor displays the intrusion position of the high-frequency noise in the transmission cable 40. Steps ST1 to ST5 are the calculation steps.

As described above, the noise intrusion position estimation device according to the first embodiment is capable of determining an intrusion position of noise that has intruded into a transmission cable from measurement results on a basis of two observation points of the transmission cable.

The noise intrusion position estimation device 100 according to the first embodiment includes not only a device including all of the measurement unit 10, the analysis setting and model inputting unit 20, and the calculation unit 30, which are the components illustrated in FIG. 1 but also a system in which a plurality of devices are used as a set, the devices obtained by dividing into each of the measurement unit 10, the analysis setting and model inputting unit 20, and the calculation unit 30.

In a case of a system in which it is divided into each of the measurement unit 10, the analysis setting and model inputting unit 20, and the calculation unit 30, existing devices can be used as each of the devices, and there is an advantage that the cost can be reduced.

### Second Embodiment

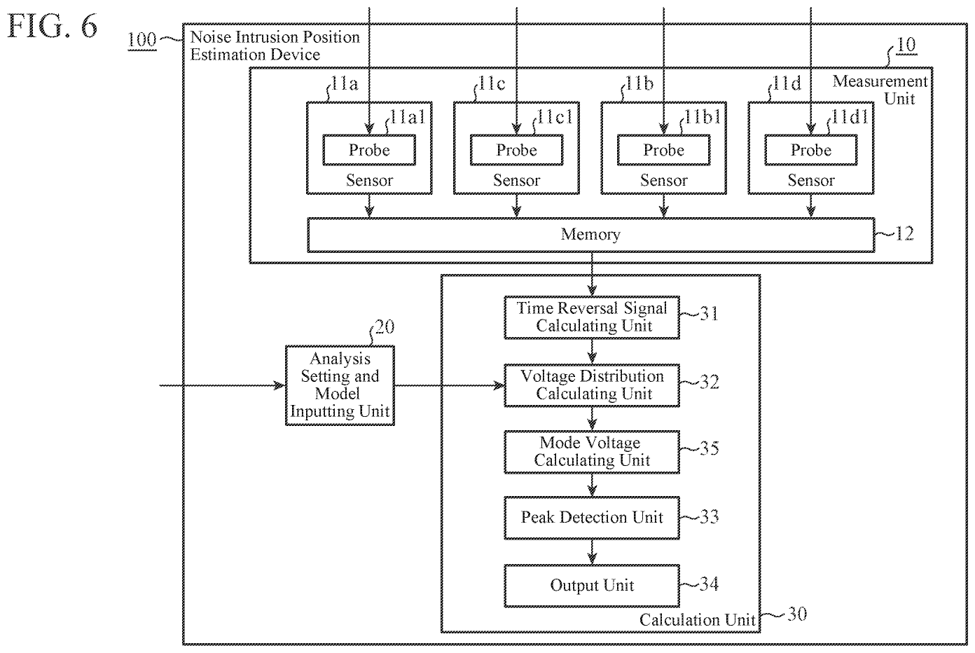

A noise intrusion position estimation device 100 according to a second embodiment will be described with reference to FIGS. 6 to 8.

The noise intrusion position estimation device 100 according to the second embodiment is operated for a transmission cable 40 having a differential pair of signal conductors and is obtained by modifying the noise intrusion position estimation device 100 according to the first embodiment by including a pair of two pairs of detection units 11a and 11c and detection units 11b and 11d for each of the differential pair of signal conductors 40a and 40b in a measurement unit 10 and adding a mode voltage calculating unit 35 to a calculation unit 30, and the other points are the same as those of the noise intrusion position estimation device 100 according to the first embodiment.

Note that the same symbols in the drawings denote the same or corresponding parts.

The measurement unit 10 includes a pair of sensors 11a and 11b corresponding to the signal conductor 40a which is one of the differential pair of signal conductors in the transmission cable 40, a pair of sensors 11c and 11d corresponding to the signal conductor 40b which is the other one of the differential pair of signal conductors, and a storage unit 12.

That is, the first sensor 11a and the third sensor 11c constitute one of the pair of sensors and behave similarly to the first sensor in the first embodiment. The second sensor 11b and the fourth sensor 11d constitute the other sensors of the pair of sensors and behave similarly to the second sensor in the first embodiment. The one pair of sensors 11a and 11c and the other pair of sensors 11b and 11d constitute a pair of sensors.

The sensors 11a to 11d are detection units that simultaneously measure temporal changes in noise waveforms.

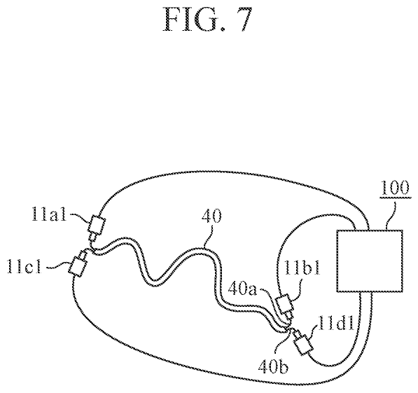

As illustrated in FIG. 7, a probe 11a1 of the sensor 11a is connected to a first end of the signal conductor 40a which is one of the signal conductors of the transmission cable 40, that is, an observation point on a first end side of two observation points. As illustrated in FIG. 7, a probe 11b1 of the sensor 11b is connected to a second end of the signal conductor 40a which is one of the signal conductors of the transmission cable 40, that is, the observation point on a second end side of the two observation points.

As illustrated in FIG. 7, a probe 11c1 of the sensor 11c is connected to a first end of the other signal conductor 40b of the transmission cable 40, that is, an observation point on a first end side. As illustrated in FIG. 7, a probe 11d1 of the sensor 11d is connected to a second end of the other signal conductor 40b of the transmission cable 40, that is, an observation point on a second end side.

When noise enters a specific position in the transmission cable 40, the noise is propagated through differential pair of the signal conductors 40a and 40b of the transmission cable 40, and the sensors 11a to 11d simultaneously observe noise waveforms as the voltage with respect to time at the observation points at both ends of the signal conductors 40a and 40b.

Note that, although one pair of signal conductors is illustrated as a differential pair of signal conductors, in a case where there are two or more differential pairs, it is only required a similar configuration be adopted for each signal conductor of the differential pairs.

The calculation unit 30 receives a pair of noise waveforms simultaneously measured by the measurement unit 10, time-reverses the pair of noise waveforms that has been received, performs transmission path analysis using the two observation points as the positions of signal sources of the time-reversed noise and using the time-reversed waveforms as excitation waveforms in a transmission line model (40S) from an analysis setting and model inputting unit 20 in which the electrical characteristics of the transmission cable (40) are represented, and outputs the positions of peak values of mode voltage values obtained from the transmission path analysis result as noise intrusion positions into the transmission cable (40).

In the calculation of the mode voltage values performed by the calculation unit 30, the time-reversed waveforms are used as a waveform of the differential mode for obtaining the voltage difference and a waveform of the common mode for obtaining ½ of the sum of the voltages at each of the pair of the two pairs of the sensors 11a and 11c and the sensors 11b and 11d.

The noise intrusion positions output by the calculation unit 30 are set as a mode conversion position that is a position of a peak value of the voltage values of the differential mode obtained from the waveform of the differential mode and a common noise intrusion position that is a position of a peak value of the voltage values of the common mode obtained from the waveform of the common mode.

The mode voltage refers to a differential mode voltage and a common mode voltage.

Let voltages of the differential pair of signal conductors at position x on the transmission cable 40 be v1(x) and v2(x), whereby a differential mode voltage vdiff(x) at position x on the transmission cable 40 is expressed by the following Equation (1).

vdiff(x)=v1(x)−v2(x) (1)

Meanwhile, a common mode voltage vcomm(x) is expressed by the following Equation (2).

vcomm(x)=(v1(x)+v2(x))/2 (2)

The calculation unit 30 includes the time reversal signal calculating unit 31, the voltage distribution calculating unit 32, the mode voltage calculating unit 35, the peak detection unit 33, and the output unit 34 and is configured by a CPU or a microprocessor.

The time reversal signal calculating unit 31 and the voltage distribution calculating unit 32 have functions similar to those of the first embodiment.

The mode voltage calculating unit 35 has both a function of obtaining a mode conversion position and a function of obtaining a common noise intrusion position. Note that either one of the function of obtaining the mode conversion position and the function of obtaining the common noise intrusion position may be provided.

In the function of obtaining the mode conversion position, the mode voltage calculating unit 35 calculates the differential mode voltage vdiff(x) on the basis of the above Equation (1) by using waveforms of the differential mode for obtaining a voltage difference at one of the pair of the two pairs of the sensors (11a and 11c) and the other pair of the sensors (11b and 11d) for the voltage current distribution at the time t from the voltage distribution calculating unit 32 and every voltage current distribution at the time (t−Δt×n) obtained by subtracting the minute time Δt set by the analysis setting and model inputting unit 20.

When the calculation of the voltage current distributions by the voltage distribution calculating unit 32 is completed, the mode voltage calculating unit 35 outputs, as the mode conversion position, the position of the peak value among the voltage values of the differential mode voltage vdiff(x) at every minute times Δt that have been calculated until the calculation of the voltage distribution calculating unit 32 has been completed.

On the other hand, in the function of obtaining the common noise intrusion position, the mode voltage calculating unit 35 calculates the common mode voltage vcomm(x) on the basis of the above Equation (2) by using waveforms of the common mode for obtaining a sum of voltages at one of the pair of the two pairs of the sensors (11a and 11c) and the other pair of the sensors (11b and 11d) for the voltage current distribution at the time t from the voltage distribution calculating unit 32 and every voltage current distribution at the time (t−Δt×n) obtained by subtracting the minute time Δt set by the analysis setting and model inputting unit 20.

When the calculation of the voltage current distributions by the voltage distribution calculating unit 32 is completed, the mode voltage calculating unit 35 outputs, as the common noise intrusion position, the position of the peak value among the voltage values of the common mode voltage vcomm(x) at every minute times Δt that have been calculated until the calculation of the voltage distribution calculating unit 32 has been completed.

The output unit 34 outputs the mode conversion position of the noise and the common noise intrusion position on the simulator specified by the mode voltage calculating unit 35 to a monitor (not illustrated) as the mode conversion position of the noise and the noise intrusion position in the transmission cable 40.

In general, noise intrusion into the transmission cable 40 having a differential pair of signal conductors first occurs as intrusion as a common mode voltage, which is then mode-converted at an unbalanced portion on the transmission cable 40, thereby generating a differential mode voltage.

Therefore, the position of the peak value among the voltage values of the common mode voltage vcomm(x) obtained in the function of obtaining the common noise intrusion position in the mode voltage calculating unit 35 specifies the noise intrusion position in the transmission cable 40.

Furthermore, the position of the peak value among the voltage values of the differential mode voltage vdiff(x) obtained in the function of obtaining the mode conversion position in the mode voltage calculating unit 35 specifies the mode conversion position (unbalanced portion) of the noise in the transmission cable 40.

Next, the operation of the noise intrusion position estimation device 100 will be described.

When high-frequency noise is superimposed on the transmission cable 40 to be measured, one of the pair of the two pairs of the sensors 11a, 11c and the other pair of the sensors 11b, 11d in the measurement unit 10 detect high-frequency noise via one of a pair of the pairs of the probes 11a1 and 11c1 and the other pair of the probes 11b1 and 11d1 connected to the two separated observation points of the pair of signal conductors in the transmission cable 40 and simultaneously measure the temporal changes of the noise waveforms.

The waveforms of the noise having temporal changes that have been simultaneously measured by one pair of the sensors 11a and 11c and the other pair of the sensors 11b and 11d of the pair of the pairs of sensors are stored in the storage unit. The above steps are measurement steps.

The noise waveforms having temporal changes that have been simultaneously measured and are stored in the storage unit 12 are read by the calculation unit 30, and the calculation unit 30 estimates the noise intrusion position in the transmission cable 40.

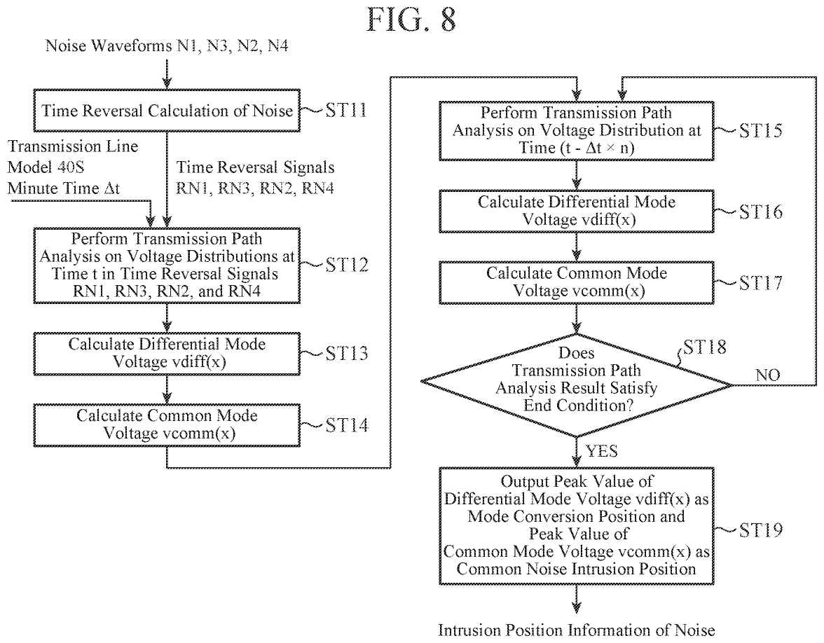

The operation of estimating the noise intrusion position performed by the calculation unit 30 will be described with reference to a flowchart illustrated in FIG. 8.

First, in step ST11, a pair of pairs of noise waveforms N1 and N3 and noise waveforms N2 and N4 that has been simultaneously measured and input is time-reversed and converted into time reversal signals RN1 and RN3 and time reversal signals RN2 and RN4, respectively, by the time reversal signal calculating unit 21.

Next, in step ST12, the voltage distribution calculating unit 32 sets both ends of the transmission cable 40 as the positions of the signal sources of the time reversal signals RN1 and RN3 and the time reversal signals RN2 and RN4 in the transmission line model 40S from the analysis setting and model inputting unit 20. The voltage distribution calculating unit 32 performs the transmission path analysis using the FDTD method in which the time is traced back and the time reversal signals RN1 and RN3 and the time reversal signals RN2 and RN4 from the time reversal signal calculating unit 31 are used as excitation waveforms. First, the voltage distribution calculating unit 32 calculates voltage current distributions at the time tin the time reversal signals RN1 and RN3 and the time reversal signals RN2 and RN4 and provides the calculation result to the mode voltage calculating unit 35.

In step ST13, the mode voltage calculating unit 35 calculates the differential mode voltage vdiff(x) from the above Equation (1).

In step ST14, the mode voltage calculating unit 35 calculates the common mode voltage vcomm(x) from the above Equation (2).

Next, in step ST15, voltage current distributions at time t−Δt (n=1) in the time reversal signals RN1 and RN3 and the time reversal signals RN2 and RN4 from the time reversal signal calculating unit 31 are calculated, and the calculation result is provided to the mode voltage calculating unit 35.

The mode voltage calculating unit 35 calculates the differential mode voltage vdiff(x) in step ST16, calculates the common mode voltage vcomm(x) in step ST17, and the process proceeds to step ST18.

In step ST18, it is determined whether or not the transmission path analysis result satisfies any one of the end conditions of (t−Δt×n)≤0, satisfying the number of times of repetitions of calculation by the voltage distribution calculating unit 32, or satisfying the rewinding time.

If no end condition is satisfied, Δt is multiplied by a value obtained by adding 1 to the value of n, the process returns to step ST15, and the voltage current distributions in the time reversal signals RN1 and RN3 and the time reversal signals RN2 and RN4 at time t−Δt×2 (n=2) are calculated. Then the process proceeds to step ST16, step ST17, and step ST18, and step ST18→step ST15→step ST16→step ST17→step ST18 are repeated until the transmission path analysis result satisfies an end condition in step ST18.

That is, the voltage distribution calculating unit 32 calculates voltage current distributions in the time reversal signals RN1 and RN3 and the time reversal signals RN2 and RN4 by tracing back the time from time t until an end condition is satisfied.

In step ST18, if the transmission path analysis result satisfies an end condition, the process proceeds to step ST19, the position of the peak value among the voltage values of the differential mode voltage vdiff(x) obtained by the mode voltage calculating unit 35 is output to the monitor as the mode conversion position, and the position of the peak value among the voltage values of the common mode voltage vcomm(x) obtained by the mode voltage calculating unit 35 is output to the monitor as the common noise intrusion position.

As a result, the common noise intrusion position and the mode conversion position (unbalanced portion) of the high-frequency noise in the transmission cable 40 are displayed on the monitor, the intrusion position of the high-frequency noise in the transmission cable 40 can be specified with high accuracy, and the mode conversion position (unbalanced portion) can be specified, whereby more appropriate noise countermeasures can be implemented.

Steps ST11 to ST18 are the calculation steps.

Note that, in the second embodiment, the voltage distribution calculating unit 32 has both the function of obtaining the mode conversion position and the function of obtaining the common noise intrusion position; however, the voltage distribution calculating unit 32 may have only one of the functions depending on the application.

Note that it is possible include a flexible combination of the embodiments, a modification of any component of the embodiments, or omission of any component in the embodiments.

### INDUSTRIAL APPLICABILITY

A noise intrusion position estimation device according to the present disclosure is suitable for a device that estimates an intrusion position of high-frequency noise into a transmission cable that is used in a balanced transmission path having a pair of signal conductors that propagates a high-frequency signal.

### REFERENCE SIGNS LIST

100: noise intrusion position estimation device, 10: measurement unit, 11a: first sensor, 11b: second sensor, 11c: third sensor, 11d: fourth sensor, 11a1 to 11d1: probe, 12: memory, 20: analysis setting and model inputting unit, 30: calculation unit, 31: time reversal signal calculating unit, 32: voltage distribution calculating unit, 33: peak detection unit, 34: output unit, 35: mode voltage calculating unit, 40: transmission cable

1. A noise intrusion position estimation device comprising:
a measurement device comprising a pair of pairs of detectors to simultaneously measure a temporal change of waveforms of noise on a transmission cable at two separated observation points in the transmission cable comprising a pair of signal conductors; and
a processing circuitry to receive, from the measurement device, a pair of pairs of the waveforms of the noise simultaneously measured, to time-reverse the pair of the pairs of the waveforms of the noise that has been received, to perform transmission path analysis in which the two separated observation points are set as positions of signal sources of the time-reversed noise and the time-reversed waveforms are set as excitation waveforms in a transmission line model in which an electrical characteristic of the transmission cable is represented, and to output a position of a peak value among mode voltage values obtained from a result of the transmission path analysis as an intrusion position of the noise into the transmission cable,
wherein, in calculation of the mode voltage values performed by the processing circuitry, the time-reversed waveforms are used in the calculation as waveforms of a common mode for obtaining ½ of a sum of voltages in each of a first pair of detectors and a second pair of detectors of the pair of the pairs of the detectors, and
the intrusion position of the noise output by the processing circuitry is set as a common noise intrusion position which is a position of a peak value among voltage values of the common mode obtained from a result of transmission path analysis performed on a basis of the waveforms of the common mode.

2. A noise intrusion position estimation device comprising:
a measurement device comprising a pair of pairs of detectors to simultaneously measure a temporal change of waveforms of noise on a transmission cable at two separated observation points in the transmission cable comprising a differential pair of signal conductors; and
processing circuitry to receive, from the measurement device, a pair of pairs of the waveforms of the noise simultaneously measured, to time-reverse the pair of the pairs of the waveforms of the noise that has been received, to perform transmission path analysis in which the two separated observation points are set as positions of signal sources of the time-reversed noise and the time-reversed waveforms are set as excitation waveforms in a transmission line model in which an electrical characteristic of the transmission cable is represented, and to output a position of a peak value among mode voltage values obtained from a result of the transmission path analysis as an intrusion position of the noise into the transmission cable,
wherein in calculation of the mode voltage values performed by the processing circuitry, the time-reversed waveforms are used in the calculation as waveforms of a differential mode for obtaining a voltage difference and as waveforms of a common mode for obtaining ½ of a sum of voltages in a first pair of detectors and a second pair of detectors of the pair of the pairs of the detectors, respectively, and
the intrusion position of the noise output by the processing circuitry is estimated as a mode conversion position which is a position of a peak value among voltage values of the differential mode obtained from the waveforms of the differential mode and as a common noise intrusion position which is a position of a peak value among voltage values of the common mode obtained from the waveforms of the common mode.

3. A noise intrusion position estimation method comprising:
simultaneously measuring a temporal change of waveforms of noise on a transmission cable at two separated observation points in the transmission cable comprising a differential pair of signal conductors; and
time-reversing a pair of pairs of the waveforms of the noise that has been simultaneously measured in the measuring, setting, in a transmission line model in which an electrical characteristic of the transmission cable is represented, the two separated observation points as positions of signal sources of the time-reversed noise, setting the time-reversed waveforms as waveforms of a differential mode for obtaining a voltage difference, setting the time-reversed waveforms as waveforms of a common mode for obtaining ½ of a sum of voltages, setting a position of a peak value among voltage values of the differential mode obtained from the waveforms of the differential mode as a mode conversion position in the transmission cable, and setting a position of a peak value among voltage values of the common mode obtained from the waveforms of the common mode as a common noise intrusion position in the transmission cable.
